(19) United States
(12) Patent Application Publication
(10) Pub. No.: US 2024/0196566 A1
(43) Pub. Date: Jun. 13, 2024

(54) FACILITATING HEAT DISSIPATION AND ELECTROMAGNETIC SHIELDING

(71) Applicant: Continental Automotive Systems, Inc., Auburn Hills, MI (US)

(72) Inventors: David Teteak, Crystal Lake, IL (US); Jake Cassin, Lake In The Hills, IL (US)

(73) Assignee: Continental Automotive Systems, Inc., Auburn Hills, MI (US)

(21) Appl. No.: 18/076,530

(22) Filed: Dec. 7, 2022

(51) Int. Cl. H05K 7/20; H05K 9/00

(52) U.S. Cl. CPC H05K 7/2039; H05K 9/0007

(57) ABSTRACT

An apparatus may be used with at least one heat dissipation element which may have one or more protrusions. The apparatus may include a body which may be shaped and dimensioned in a manner so as to be capable of covering at least one component, including at least one opening defined and/or mating with the heat dissipation element in a manner such that the protrusion(s) may at least be positionally aligned with the opening(s) so as to be capable of being thermally coupled to the component(s) to facilitate heat dissipation of heat generated by the component(s). When mated, contact may be established between the body and the heat dissipation element(s) such that an electromagnetic compatibility (EMC) type enclosure may be formed.

### BACKGROUND

A vehicle may carry one or more components/modules. Such components/modules may generate heat (e.g., electronic components/modules which may generate heat during operation) and/or potentially be associated with electromagnetic compatibility (EMC) related issue(s) such as electromagnetic interference (EMI) and EM noise.

EMC related issues may, for example, be addressed by manner of shielding (e.g., shielding of a component). However, it is appreciable that shielding may potentially impact heat dissipation of a heat generating component which has been shielded.

It is to be appreciated that generated heat would typically need to be dissipated as overheating may potentially result in malfunction. However, shielding may potentially affect heat dissipation effectiveness.

Therefore, the present disclosure contemplates that it would be helpful to address, or at least mitigate, one or more issues which could be posed by challenge(s) to heat dissipation in view of shielding.

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### BRIEF SUMMARY

In accordance with embodiment(s) of the disclosure, there is provided an apparatus. The apparatus may, for example, be used with at least one heat dissipation element (e.g., a heatsink) which may have one or more protrusions. The apparatus may include a body (e.g., a covering) which may be shaped and dimensioned in a manner so as to be capable of covering at least one component, including at least one opening defined and/or mating with the heat dissipation element in a manner such that the protrusion(s) may at least be positionally aligned with the opening(s) so as to be capable of being thermally coupled to the component(s) to facilitate heat dissipation of heat generated by the component(s). When mated (i.e., when the apparatus is coupled to the heat dissipation element(s)), contact may be established between the body and the heat dissipation element(s) such that an electromagnetic compatibility (EMC) type enclosure may be formed.

In the above manner, it is generally contemplated that heat dissipation of heat generated by component(s) which has/have been shielded (e.g., in view of Electromagnetic Compatibility (EMC) related concern(s)/issue(s)) may possibly be facilitated (e.g., protrusion(s) of a heatsink which may be positioned adjacent to heat generating component(s)) in an effective/efficient manner possibly without compromising effectiveness of shielding (e.g., in view of EMC related concern(s)/issue(s)) as the heatsink may also be configured to form a part/portion of an EMC type enclosure.

In accordance with embodiment(s) of the disclosure, there is provided an assembly. The assembly may include at least one heat dissipation element (e.g., a heatsink) and at least one apparatus. The heat dissipation element(s) may, for example, include at least one protrusion. The apparatus may, for example, be coupled to the heat dissipation element(s). The apparatus may include a body (e.g., a covering) shaped and dimensioned in a manner so as to be capable of housing at least one component and/or including at least one opening defined. The heat dissipation element(s) and the apparatus may be capable of being coupled (e.g., mated) in a manner such that the protrusion(s) may at least be positionally aligned with the opening(s). The protrusion(s) may be capable of being thermally coupled to the component(s) to facilitate heat dissipation of heat generated by the component(s). When the heat dissipation element(s) and the apparatus (102) are coupled, contact may be established between the body and the heat dissipation element(s) such that an electromagnetic compatibility (EMC) type enclosure may be formed.

In the above manner, it is generally contemplated that heat dissipation of heat generated by component(s) which has/have been shielded (e.g., in view of Electromagnetic Compatibility (EMC) related concern(s)/issue(s)) may possibly be facilitated (e.g., protrusion(s) of a heatsink which may be positioned adjacent to heat generating component(s)) in an effective/efficient manner possibly without compromising effectiveness of shielding (e.g., in view of EMC related concern(s)/issue(s)) as the heatsink may also be configured to form a part/portion of an EMC type enclosure.

Other objects, features and characteristics, as well as the methods of operation (where/if applicable) and the functions of the related elements of the structure, the combination of parts and economics of manufacture will become more apparent upon consideration of the following detailed description and appended claims with reference to the accompanying drawings, all of which form a part of this specification. It should be understood that the detailed description and specific examples, while indicating the non-limiting embodiments of the disclosure, are intended for purposes of illustration only and are not intended to limit the scope of the disclosure

### BRIEF DESCRIPTION OF THE DRAWINGS

The present disclosure will become more fully understood from the detailed description and the accompanying drawings, wherein:

FIG. 1a shows a first example of an unassembled view of the assembly, in accordance with an embodiment of the disclosure.

FIG. 1b shows a second example of an unassembled view of the assembly, in accordance with an embodiment of the disclosure.

FIG. 1c shows a third example of an unassembled view of the assembly, in accordance with an embodiment of the disclosure.

FIG. 1d shows an example of an assembled view of the assembly, in accordance with an embodiment of the disclosure.

FIG. 2 depicts the apparatus of FIGS. 1a-1d in further detail, according to an embodiment of the disclosure.

### DETAILED DESCRIPTION

It should be understood that like reference numerals identify corresponding or similar elements throughout the several drawings. It should be understood that although a particular component arrangement is disclosed and illustrated in these exemplary embodiments, other arrangements could also benefit from the teachings of this disclosure.

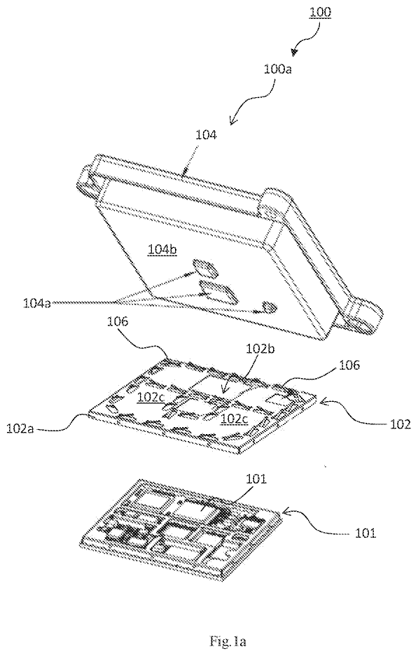

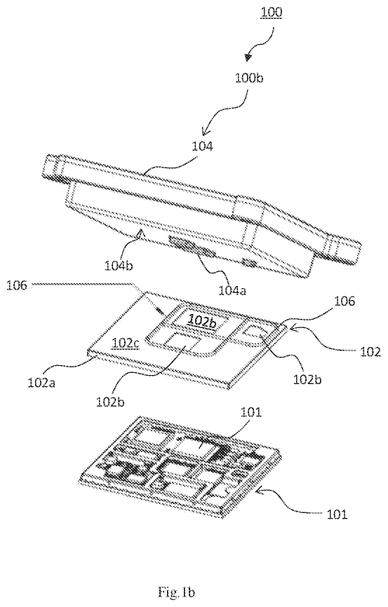

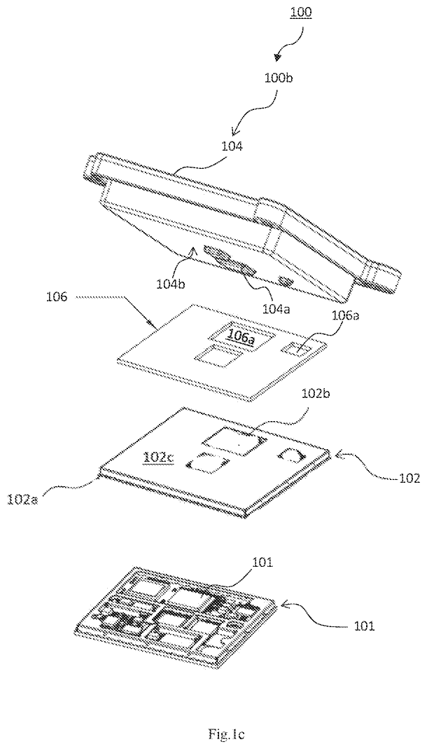

Referring to FIG. 1a to FIG. 1d, an assembly 100 is shown, according to an embodiment of the disclosure. FIG. 1a shows a first example of an unassembled view 100a of the assembly 100, in accordance with an embodiment of the disclosure, FIG. 1b shows a second example of an unassembled view 100b of the assembly 100, in accordance with an embodiment of the disclosure, FIG. 1c shows a third example of an unassembled view 100c of the assembly 100, in accordance with an embodiment of the disclosure and FIG. 1d shows an example of an assembled view 100d of the assembly 100, in accordance with an embodiment of the disclosure.

The assembly 100 may be suitable for facilitating electromagnetic (EM) shielding and for facilitating heat dissipation, in accordance with an embodiment of the disclosure. Moreover, the assembly 100 may, for example, be suitable for use in connection with/be associated with a vehicle (not shown), in accordance with an embodiment of the disclosure.

Specifically, the assembly 100 may be suitable for the facilitation of EM shielding and heat dissipation of one or more components/modules 101 which may, for example, be carried by a base such as a printed circuit board (PCB), in accordance with an embodiment of the disclosure. The base may, for example, be carried by a vehicle, in accordance with an embodiment of the disclosure. A component/module 101 may, for example, be electrical/electronic-based (e.g., radio-frequency coil element, integrated circuit chip) which may possibly generate heat whilst in operation and may possibly be associated with EM compatibility (EMC) concern(s)/issue(s) such as Electromagnetic radiation, Electromagnetic interference, and/or Electromagnetic noise.

In accordance with an embodiment of the disclosure, the assembly 100 may include any one of at least one apparatus 102, at least one heat dissipation element 104, and at least one contact element 106, or any combination thereof.

In one example the assembly 100 may include the apparatus(es) 102 and the heat dissipation element(s) 104, in accordance with an embodiment of the disclosure. In another example, the assembly 100 may include the apparatus(es) 102, the heat dissipation element(s) 104, and the contact element(s) 106, in accordance with an embodiment of the disclosure.

The present disclosure contemplates that, in one embodiment, the assembly 100 may include the apparatus(es) 102, the heat dissipation element(s) 104, and the contact element(s) 106.

Generally, the apparatus(es) 102 may, for example, be coupled to the heat dissipation element(s) 104 via the contact element(s) 106. For example, coupling between the apparatus(es) 102 and the heat dissipation element(s) 104 may be by manner of contact which may be facilitated by the contact element(s) 106, in accordance with an embodiment of the disclosure. Further generally, when the apparatus(es) 102 and the heat dissipation element(s) 104 are coupled (e.g., mated), contact may be established between the apparatus 102 and the heat dissipation element 104 such that an electromagnetic compatibility (EMC) type enclosure may, for example, be formed, in accordance with an embodiment of the disclosure.

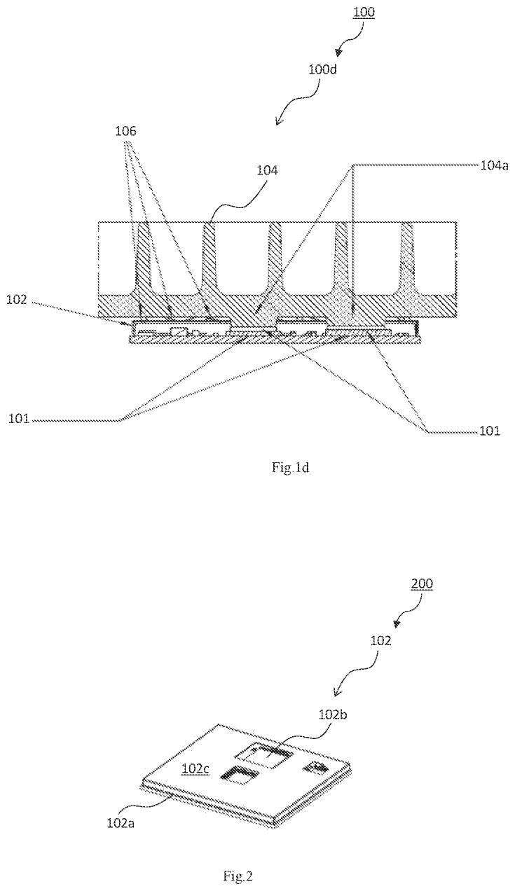

The apparatus 102 may include/correspond to a body 102a which may be shaped and dimensioned to cover/house/shield the component(s)/module(s) 101. The body 102a may, for example, be shaped and dimensioned in a manner such that one or more openings 102b (e.g., one or more windows) may be defined, in accordance with an embodiment of the disclosure. In one embodiment, the body 102a may, for example, be shaped and dimensioned such that a face 102c may be defined. The opening(s) 102b may, for example, be defined on the face 102c, in accordance with an embodiment of the disclosure. The apparatus 102 will be discussed later in further detail with reference to FIG. 2, in accordance with an embodiment of the disclosure.

The heat dissipation element(s) 104 may, for example, correspond to at least one heat sink structure (e.g., referable to as a “heatsink”) capable of dissipating heat. For example, the heat dissipation element(s) 104 may be capable of coupled (e.g., thermally coupled) to the component(s)/module(s) 101 in a manner so as to be capable of facilitating transference of heat from the component(s)/module(s) 101 (i.e., dissipating heat generated by the component(s)/module(s) 101). Thermal coupling may, for example, be by manner of disposing a thermally conductive interface compound between the component(s)/module(s) 101 and the heat dissipation element(s) 104, in accordance with an embodiment of the disclosure. The heat dissipation element(s) 104 may, for example, include one or more protrusions 104a, in accordance with an embodiment of the disclosure. For example, the heat dissipation element(s) 104 may be shaped and dimensioned such that a surface 104b may be defined, in accordance with an embodiment of the disclosure. In one embodiment, the protrusion(s) 104a may, for example, extend from the surface 104b.

The contact element(s) 106 may, for example, be one or both of:
integral with respect to one or both of the apparatus(es) 102 and the heat dissipation element(s) 104 (e.g., integrated with the apparatus(es) 102 and/or the heat dissipation element(s) 104); and
distinct and separate from one or both of the apparatus(es) 102 and the heat dissipation element(s) 104 (e.g., discrete with respect to the apparatus(es) 102 and/or the heat dissipation element(s) 104).

In one embodiment, the contact element(s) 106 may, for example, be integrated with the apparatus(es) 102 and/or the heat dissipation element(s) 104. In another embodiment, the contact element(s) 106 may, for example, be discrete with respect to the apparatus(es) 102 and/or the heat dissipation element(s) 104. In yet another embodiment, the contact element(s) 106 may, for example, be both integrated and discrete with respect to the apparatus(es) 102 and/or the heat dissipation element(s) 104 (e.g., some of the contact element(s) 106 may be discrete with respect to the apparatus(es) 102 and/or the heat dissipation element(s) 104 whereas some of the contact element(s) 106 may be integrated with the apparatus(es) 102 and/or the heat dissipation element(s) 104).

The foregoing will now be discussed in further detail based on a first example scenario, a second example scenario, and a third example scenario, in accordance with an embodiment of the disclosure, hereinafter.

The first example scenario may be associated with the aforementioned first example of an unassembled view 100a of the assembly 100, in accordance with an embodiment of the disclosure. The second example scenario may be associated with the aforementioned second example of an unassembled view 100b of the assembly 100, in accordance with an embodiment of the disclosure. The third example scenario may be associated with the aforementioned third example of an unassembled view 100c of the assembly 100, in accordance with an embodiment of the disclosure.

Generally, in the first, second, and third scenarios, the aforementioned component(s)/module(s) 101 may, for example, correspond a plurality of components carried by a PCB/at least a portion of a PCB, and the PCB may, for example, be carried by a vehicle (not shown). Moreover, the component(s) carried by the PCB may, for example, be associated with EMC related concern(s)/issue(s) and/or heat dissipation related concern(s)/issue(s). In one example, one or more components 101 carried by the PCB may be associated with EMC related concern(s)/issue(s) and one or more other components 101 may be associated with heat dissipation related concern(s)/issue(s). In another example, one or more components 101 carried by the PCB may be associated with EMC related concern(s)/issue(s) and heat dissipation related concern(s)/issue(s). Moreover, the body 102a may, for example, correspond to a covering (e.g., a shield/casing/housing) 102a. Additionally, the heat dissipation element(s) 104 may, for example, correspond to one or more heatsink 104 which may include one or more protrusions 104a extending from the surface(s) 104b of the heatsink(s) 104.

With regard to the first example scenario which may be associated with the aforementioned first example of an unassembled view 100a of the assembly 100 as shown in FIG. 1a, in accordance with an embodiment of the disclosure, the covering 102a may, for example, be shaped and dimensioned in a manner so as to be capable of at least covering/housing/shielding the component(s) 101. The opening(s) 102b may, for example, be positionally aligned with the component(s) 101. For example, the opening(s) 102b may be positionally aligned with the component(s) 101 such that the opening(s) 102b may correspond to area(s) (e.g., window(s)) via which the component(s) 101 may be considered to be exposed and accessible from outside of the covering 102a. In a specific example, though the component(s) 101 may be considered to be covered by the covering 102a, the component(s) 101 may (still) be accessible (i.e., from outside of the covering 102a) for coupling to the heatsink(s) 104. In a more specific example, an apparatus 102 may be coupled (e.g., mated) with a heatsink 104 in a manner such that the protrusion(s) 104a may at least be positionally aligned with respect to the opening(s) 102b such that the protrusion(s) 104a may possibly be coupled (e.g., thermally coupled) to the component(s) 101 so as to facilitate the possibility of dissipation of heat generated by the component(s) 101 (i.e., which is/are considered to be covered by the covering 102a).

In the first example scenario, when coupled (e.g., mated), contact between the covering 102a and the heatsink 104 (e.g., the face 102c and the surface 104b may be facing each other) may be established such that an electromagnetic compatibility (EMC) type enclosure may, for example, be formed (e.g., an electrically EMC sealed enclosure may be formed). In one example, the covering 102a may be coupled to a ground (i.e., electric ground in the PCB), and a heatsink 104 may effectively be considered to be coupled to ground by virtue of contact being established between the covering 102a and the heatsink 104. In another example, a heatsink 104 may be coupled to ground (e.g., to the chassis/body of a vehicle) and a covering 102a may effectively be considered to be coupled to ground by virtue of contact being established between the covering 102a and the heatsink 104. In yet another example, both the covering 102a and the heatsink 104 may be coupled to ground.

Moreover, in the first example scenario, contact between the covering 102a and the heatsink 104 may be based on direct contact such that at least one portion of the covering 102a may directly contact the heatsink 104, in accordance with an embodiment of the disclosure. For example, the covering 102a may be shaped and dimensioned in a manner such that one or more contact points may be defined and the contact point(s) may be capable of establishing contact between the covering 102a and the heatsink 104 when the covering 102a and the heatsink 104 are coupled. The contact point(s) may, for example, correspond to the aforementioned contact element(s) 106, in accordance with an embodiment of the disclosure.

In this regard, in the first example scenario, it is appreciable that the aforementioned contact element(s) 106 (i.e., contact point(s)) may be considered to be integral with respect to the apparatus 102 (i.e., the contact element(s) 106 may be considered to be an integral part of the apparatus 102). For example, the contact point(s) may be defined on the face 102c of the covering 102a. In one specific example, when an apparatus 102 is coupled (e.g., mated) to a heatsink 104, the face 102c of the covering 102a may be facing the heatsink 104 and contact between an apparatus 102 and a heatsink 104 may be established based on the contact point(s). In one embodiment, the contact point(s) may be defined on the face 102c of the covering 102a such that the opening(s) 102b may, for example, be surrounded (e.g., the contact point(s) may be defined adjacent to and around the opening(s) 102b). In another embodiment, the contact point(s) may, for example, be defined along the periphery of the face 102c of the covering 102a (e.g., effectively surrounding the opening(s) 102b in a broad manner). In yet another embodiment, the contact point(s) (e.g., a first set of contact points) may be defined on the face 102c of the covering 102a such that the opening(s) 102b may, for example, be surrounded (e.g., the first set of contact points may be defined adjacent to and around the opening(s) 102b) and the contact point(s) (e.g., a second set of contact points) may be defined along the periphery of the face 102c of the covering 102a (e.g., the second set of contact points may be considered to be further from the opening(s) 102b as compared to the first set of contact points in terms of proximity, but yet may still be considered to be effectively surrounding the opening(s) 102b in a broader sense since the second set of contact points are defined along the periphery of the face 102c of the covering 102a). In one example, the contact point(s) may, for example, correspond to one or more spring contacts.

The spring contact(s) may, for example, include one or both of a first set of spring contacts and a second set of spring contacts, in accordance with an embodiment of the disclosure. Each of the first set of spring contacts and the second set of spring contacts may, for example, include a first spring contact and a second spring contact, in accordance with an embodiment of the disclosure. In one example, the first and second spring contacts may be a portion of a first set of spring contacts surrounding an opening 102b, in accordance with an embodiment of the disclosure. In another example, the first and second spring contacts may be a portion of a second set of spring contacts defined along the periphery of the face 102c, in accordance with an embodiment of the disclosure. The first spring contact may, for example, be distinct and separate from the second spring contact in the sense that the first spring contact may contact one part of the heatsink 104 whereas the second spring contact may contact another part (i.e., a different part relative to the part contacted by the first spring contact) of the heatsink 104, in accordance with an embodiment of the disclosure.

It is appreciable that, in the first example scenario, contact between the covering 102a and the heatsink 104 may be considered to be based on direct contact as the contact point(s) may, for example, be considered to be integral part(s)/portion(s) of the apparatus 102 (e.g., specifically, integral portion(s)/part(s) of the covering 102a), in accordance with an embodiment of the disclosure.

With regard to the second example scenario which may be associated with the aforementioned second example of an unassembled view 100b of the assembly 100 as shown in FIG. 1b, in accordance with an embodiment of the disclosure, it is to be noted that the second example scenario may be analogous to the first example scenario with the exception of the contact point(s). In this regard, it is appreciable that, where relevant, portion(s) of the foregoing discussion concerning the first example scenario may analogously apply in the context of the second scenario.

Specifically, in analogous manner with respect to the first example scenario, in the second example scenario, contact between the covering 102a and the heatsink 104 may be based on direct contact such that at least one portion of the covering 102a may directly contact the heatsink 104, in accordance with an embodiment of the disclosure. For example, the covering 102a may be shaped and dimensioned in a manner such that one or more contact points may be defined, and the contact point(s) may be capable of establishing contact between the covering 102a and the heatsink 104 when the covering 102a and the heatsink 104 are coupled. The contact point(s) may, for example, correspond to the aforementioned contact element(s) 106, in accordance with an embodiment of the disclosure.

In contrast to the contact point(s) discussed per the first example scenario, in the second example scenario, a contact point may, for example, correspond to a continuous perimeter (e.g., rather than a first spring contact which may be separate and distinct from a second spring contact) contacting a heatsink 104 when the covering 102a of an apparatus 102 and the heatsink 104 are coupled (e.g., mated), in accordance with an embodiment of the disclosure. A continuous perimeter may, for example, correspond to a loop. In one example, a contact point may correspond to a continuous perimeter (e.g., in the form of a loop) which may be defined in a manner so as to be surrounding an opening 102b. In another example, a contact point may correspond to a continuous perimeter (e.g., in the form of a loop) defined along the periphery of the face 102c. In yet another example, a first contact point corresponding to a continuous perimeter (e.g., in the form of a loop) may be defined in a manner so as to be surrounding an opening 102b, and a second contact point corresponding a continuous perimeter (e.g., in the form of a loop) may be defined along the periphery of the face 102c.

In the second example scenario, a contact point may, for example, correspond to an Electromagnetic Compatibility (EMC) Radio Frequency (RF) dispensed compound, in accordance with an embodiment of the disclosure.

As with the first example scenario, it is appreciable that, in the second example scenario, contact between the covering 102a and the heatsink 104 may be considered to be based on direct contact as the contact point(s) may, for example, be considered to be integral part(s)/portion(s) of the apparatus 102 (e.g., specifically, integral portion(s)/part(s) of the covering 102a), in accordance with an embodiment of the disclosure.

With regard to the third example scenario which may be associated with the aforementioned third example of an unassembled view 100c of the assembly 100 as shown in FIG. 1c, in accordance with an embodiment of the disclosure, it is to be noted that the third example scenario may be analogous to the first example scenario and/or the second example scenario with the exception of the contact point(s). In this regard, it is appreciable that, where relevant, portion(s) of the foregoing discussion concerning the first and/or second example scenarios may analogously apply in the context of the third scenario.

Specifically, in contrast to the first and second example scenarios, in the third example scenario, contact between the covering 102a and the heatsink 104 may be based on indirect contact (i.e., the covering 102a may be considered to be in indirect contact with the heatsink 104), in accordance with an embodiment of the disclosure. In one embodiment, indirect contact as between an apparatus 102 (e.g., the covering 102a of the apparatus 102) and a heatsink 104 may be established by manner of, for example, disposing a contact layer between the covering 102a and the heatsink 104. The contact layer may, for example, correspond to the earlier discussed contact element(s) 106, in accordance with an embodiment of the disclosure. Moreover, the contact layer may, for example correspond to an Electromagnetic (EMC) pad, in accordance with an embodiment of the disclosure. Moreover, the one or more windows 106a (e.g., analogous to the opening(s) 102b) may, for example, be defined on the contact layer, in accordance with an embodiment of the disclosure.

Additionally, with regard to the third example scenario, the contact layer may, for example, coupled to ground (i.e., the contact layer may be effectively grounded). In one example, the contact layer may be coupled to the ground associated with an apparatus 102 (e.g., the covering 102a of the apparatus 102). In another example, the contact layer may be coupled to the ground associated with the heatsink 104. In yet another example, the contact layer may be coupled to the ground associated with the apparatus 102 and the ground associated with the heatsink 104. In yet another example, the contact layer may be coupled to a ground which may be considered to be distinct and separate from one or both of the ground associated with the apparatus 102 and the ground associated with the heatsink 104.

In contrast to the first and second example scenarios, it is appreciable that, in the second example scenario, contact between the covering 102a and the heatsink 104 may be considered to be based on indirect contact as a contact layer is disposed between the covering 102a and the heatsink 104 when the covering 102a and the heatsink 104 are, for example, mated. For example, the contact layer may be sandwiched between the covering 102a and the heatsink 104 when the covering 102a and the heatsink 104 are, for example, mated. Appreciably, the window(s) 106a may be positionally aligned with respect to the opening(s) 102b and/or the protrusion(s) 104a when the contact layer is, for example, sandwiched between the covering 102a and the heatsink 104, in accordance with an embodiment of the disclosure. In this regard, it is appreciable that the covering 102a and the heatsink 104 may be coupled by manner of, for example, indirect contact via the contact layer, in accordance with an embodiment of the disclosure.

Generally, with regard to the above discussed first, second, and third scenarios, when an apparatus 102 and a heatsink 104 are coupled (e.g., mated), the protrusion(s) 104a may be at least positionally aligned with respect to the opening(s) 102b (i.e., which may facilitate access to the component(s) 101). For example, as discussed earlier, the opening(s) 102b may be positionally aligned with the component(s) 101 such that the opening(s) 102b may correspond to area(s) (e.g., window(s)) via which the component(s) 101 may be considered to be exposed and accessible from outside of the covering 102a. In this regard, the protrusion(s) 104a may, in effect, be positionally aligned adjacent to the component(s) 101 such that thermal coupling between the protrusion(s) 104a and the component(s) 101 may be facilitated. In one example, the protrusion(s) 104a may be shaped and dimensioned so as to be capable of extending (e.g., partially extending or fully extending) through the opening(s) 102b so as to be at least positionally adjacent to the component(s) 101. In another example, the protrusion(s) 104a need not necessarily extend into/through the opening(s) to be positionally adjacent to the component(s) 101 (e.g., in an example situation where component height and/or thickness of a layer of thermally conductive interface compound may be such that extension of the protrusion(s) 104a into/through the opening(s) 102b may be optional). Moreover, when an apparatus 102 is coupled (e.g., mated) with the heatsink 104, contact between the covering 102a and the heatsink 104 may be established such that the heatsink 104 may be considered to be grounded (i.e., effectively grounded). Appreciably, the opening(s) 102b may be considered to have been effectively covered by a grounded heatsink 104 (e.g., the opening(s) 102b defined may, for example, be considered to be protected from EMC noise with the contact element(s) 106 touching a grounded heatsink 104). In this manner, when coupled (e.g., mated), contact between the covering 102a and the heatsink 104 may be established such that an electromagnetic compatibility (EMC) type enclosure may, for example, be formed. Moreover, in this manner, it is contemplated that shielding capability (i.e., in view of Electromagnetic Compatibility (EMC) related concern(s)/issue(s)) would possibly not be compromised even with the opening(s) 102b.

In view of the foregoing, it is appreciable that there is generally contemplated, an assembly 100 in accordance with an embodiment of the disclosure. The assembly 100 may, for example, include an apparatus 102 and a heat dissipation element 104, in accordance with an embodiment of the disclosure. The apparatus 102 may be coupled to the heat dissipation element 104.

In one embodiment, the heat dissipation element 104 (e.g., a heatsink) may include, for example one or more protrusions 104a and the apparatus 102 may include a body 102a (e.g., a covering) which may be shaped and dimensioned in a manner so as to be capable of one or both of (i.e., at least one of) covering one or more components 101 and including one or more openings 102b defined (i.e., capable of covering at least one component 101 and/or including at least one opening 102b defined). The heat dissipation element 104 and the apparatus 102 may be capable of being coupled in a manner such that the protrusion(s) 104a may at least be positionally aligned with the opening(s) 102b. Moreover, the protrusion(s) 104a may be capable of being thermally coupled to the component 101 so as to facilitate dissipation of heat which may be generated by the component(s) 101. Furthermore, when the heat dissipation element 104 and the apparatus 102 are coupled, contact may be established between the body 102a and the heat dissipation element 104 such that an electromagnetic compatibility (EMC) type enclosure may be formed.

In this regard, it is generally contemplated that heat dissipation of heat generated by component(s) which has/have been shielded (e.g., in view of Electromagnetic Compatibility (EMC) related concern(s)/issue(s)) may possibly be facilitated (e.g., protrusion(s) of a heatsink which may be positioned adjacent to heat generating component(s)) in an effective/efficient manner possibly without compromising effectiveness of shielding (e.g., in view of EMC related concern(s)/issue(s)) as the heatsink may also be configured to form a part/portion of an EMC type enclosure.

Referring to FIG. 2, the apparatus 102 (i.e., as discussed earlier with reference to the assembly 100 of FIG. 1) will be discussed in further detail based on an example context 200, in accordance with an embodiment of the disclosure.

In the example context 200, an apparatus 102 may, for example, correspond to/include a shield which may be suitable for addressing Electromagnetic Compatibility (EMC) related concern(s)/issue(s) associated with one or more components 101, in accordance with an embodiment of the disclosure. The shield may, example, be an Electromagnetic Compatibility (EMC) protected shield covering. In this regard, it is appreciable that the apparatus 102 may, for example, correspond to an EMC protected shield covering, in accordance with an embodiment of the disclosure.

As discussed earlier, an apparatus 102 may include/correspond to a body 102a (e.g., a covering) which may be shaped and dimensioned to cover/house/shield the component(s)/module(s) 101. The body 102a may, for example, be shaped and dimensioned in a manner such that one or more openings 102b (e.g., one or more windows) may be defined, in accordance with an embodiment of the disclosure. In one embodiment, the body 102a may, for example, be shaped and dimensioned such that a face 102c may be defined. The opening(s) 102b may, for example, be defined on the face 102c, in accordance with an embodiment of the disclosure.

In the example context 200, the number of openings 102b may, for example, correspond to the number of protrusions 104a. Moreover, an opening 102b may be shaped so as to match a protrusion 104a (i.e., shape/profile of a protrusion 104a). For example, a protrusion 104a may have a squarish profile and an opening 102b may be shaped so as to be in the form of a squarish window. Additionally, an opening 102b may be dimensioned (e.g., sized) so as to be capable of allowing at least partial extension (e.g., protrude) of a protrusion 104a into the body 102a. Furthermore, the body 102a may be of a height capable of accommodating (e.g., covering) the tallest component 101 which the apparatus 102 is covering. For example, body 102a may be covering a first component 101 and a second component 101 which may be of a height which is taller than the first component 101. Height of the body 102a may, for example, be taller than second component height. In this manner, the body 102a may be capable of covering both the first and second components 101.

In view of the foregoing, it is appreciable that the present disclosure contemplates an apparatus 102 (e.g., which may correspond to an Electromagnetic Compatibility (EMC) protected shield covering) usable with at least one heat dissipation element 104 (e.g., a heatsink), in accordance with an embodiment of the disclosure. The heat dissipation element 104 may, for example, include at least one protrusion 104a. The apparatus 102 may include a body 102a (e.g., a covering) which may be shaped and dimensioned in a manner so as to be capable of, for example, any one of covering at least one component 101, including at least one opening 102b defined and mating with the heat dissipation element 104, or any combination thereof (i.e., covering at least one component 101, including at least one opening 102b defined and/or mating with the heat dissipation element 104; at least one of covering at least one component 101, including at least one opening 102b defined and mating with the heat dissipation element 104). In one embodiment, the body 102a may be shaped and dimensioned in a manner so as to be capable of, for example, covering at least one component 101, including at least one opening 102b defined and mating with the heat dissipation element 104. Mating with the heat dissipation element 104 may, for example, be in a manner such that the protrusion 104a may at least be positionally aligned with the opening 102b so as to be capable of being thermally coupled to the component 101 to facilitate heat dissipation of heat generated by the component 101. Moreover, when mated, contact may be established between the body 102a and the heat dissipation element 104 such that an electromagnetic compatibility (EMC) type enclosure may be formed.

In one embodiment (e.g., as discussed earlier in the context of the first example scenario, the second example scenario and/or the third example scenario), contact established between the body 102a and the heat dissipation element 104 may be based on one or both of direct contact and indirect contact (i.e., direct contact and/or indirect contact; at least one of direct contact and indirect contact). Moreover, in one embodiment, the heat dissipation element 104 may, for example, be grounded.

In one embodiment (e.g., as discussed earlier in the context of the first example scenario), contact between the body 102a and the heat dissipation element 104 may be based on direct contact such that at least one portion of the body 102a (e.g., one or more contact elements 106 which may be defined on the face 102c) directly contacts the heat dissipation element 104 which has been grounded. In one example, the body 102a is further shaped and dimensioned so as to define at least one contact point capable of establishing contact between the body 102a and the heat dissipation element 104. In another example, the body 102a may be further shaped and dimensioned so as to define a plurality of contact points capable of establishing contact between the body 102a and the heat dissipation element 104. The contact point(s) may, for example, correspond to the aforementioned contact element(s) 106, in accordance with an embodiment of the disclosure.

In one embodiment, the body 102a may, for example, be further shaped and dimensioned in a manner such that a face 102c may be defined. When mated (i.e., when the apparatus 102 and the heat dissipation element 104 are coupled), the face 102c may, for example, be facing the heat dissipation element 104. Moreover, the contact point(s) (e.g., a plurality of contact points) may, for example, be defined on the face 102c in a manner such that the opening 102b may be at least surrounded.

In one embodiment, a plurality of contact points may, for example, correspond to a plurality of spring contacts. The plurality of spring contacts may, for example, include at least a first spring contact and a second spring contact wherein the first spring contact and second spring contact being discrete (i.e., distinct and separate) contact points to the heat dissipation element 104. Moreover, the spring contacts may, for example, be one or both of defined along the periphery of the face 102c and defined in a manner so as to surround the opening 102b (i.e., defined along the periphery of the face 102c and/or defined in a manner so as to surround the opening 102b; at least one of defined along the periphery of the face 102c and defined in a manner so as to surround the opening 102b). In one example, the spring contacts may be defined along the periphery of the face 102c. In another example, the spring contacts may be defined in a manner so as to surround the opening 102b. In yet another example, the spring contacts may be defined in a manner so as to surround the opening 102b and be defined along the periphery of the face 102c.

In one embodiment (e.g., as discussed earlier in the context of the second example scenario, in accordance with an embodiment of the disclosure), the body 102a may, for example, be further shaped and dimensioned so as to define one or more contact points capable of establishing contact between the body 102a and the heat dissipation element 104. The contact point(s) may, for example, correspond to the aforementioned contact element(s) 106, in accordance with an embodiment of the disclosure. For example, a contact point may correspond to a continuous perimeter (e.g., in the form of a loop) contacting the heat dissipation element 104 when the body 102a and the heat dissipation element 104 are mated (e.g., coupled). A contact point may, for example, correspond to a continuous perimeter which may be one or both of defined along the periphery of the face 102c and defined around the opening 102b (i.e., defined along the periphery of the face 102c and/or around the opening 102b; at least one of defined along the periphery of the face 102c and/or around the opening 102b). In one example, the body 102a may be further shaped and dimensioned so as to define a first contact point which may correspond to a continuous perimeter which may be defined around the opening 102b. In another example, the body 102a may be further shaped and dimensioned so as to define a second contact point which may correspond to a continuous perimeter which may be defined along the periphery of the face 102c. In yet another example, the body 102a may be further shaped and dimensioned so as to define a first contact point which may correspond to a continuous perimeter which may be defined along the periphery of the face 102c and the body 102a may be further shaped and dimensioned so as to define a second contact point which may correspond to a continuous perimeter which may be defined around the opening 102b. A contact point (e.g., the first contact point and/or the second contact point) may, for example, correspond to an Electromagnetic Compatibility (EMC) Radio Frequency (RF) dispensed compound, in accordance with an embodiment of the disclosure.

In one embodiment (e.g., as discussed earlier in the context of the third example scenario, in accordance with an embodiment of the disclosure), indirect contact may, for example, be established between the body 102a and the heat dissipation element 104 by manner of a contact layer which may be disposed between the body 102a and the heat dissipation element 104. The contact layer may, for example, correspond to the earlier discussed contact element(s) 106, in accordance with an embodiment of the disclosure. The contact layer may, for example, be discrete (i.e., distinct and separate) with respect to one or both of the body 102a and the heat dissipation element 104 (i.e., the body 102a and/or the heat dissipation element 104; at least one of the body 102a and the heat dissipation element 104, in accordance with an embodiment of the disclosure. The contact layer may, for example, correspond to an Electromagnetic Compatibility (EMC) pad, in accordance with an embodiment of the disclosure.

In one embodiment, it is generally contemplated that the protrusion(s) 104a (of the heat dissipation element(s) 104) may, for example, be shaped and dimensioned so as to be capable of extending through, for example, the opening(s) 102b (of the apparatus 102) so as to be at least positionally adjacent to the component(s) 101 such that thermal coupling between the protrusion(s) 104a and the component(s) 101 may, for example, be capable of being facilitated.

In one embodiment, it is generally contemplated that the protrusion(s) 104a (of the heat dissipation element(s) 104) may, for example, be positionally aligned with, for example, the opening(s) 102b (of the apparatus 102) so as to be positionally aligned with the component(s) 101 such that thermal coupling between the protrusion(s) 104a and the component(s) 101 may, for example, be capable of being facilitated.

In the above manner, it is generally contemplated that heat dissipation of heat generated by component(s) which has/have been shielded (e.g., in view of Electromagnetic Compatibility (EMC) related concern(s)/issue(s)) may possibly be facilitated (e.g., protrusion(s) of a heatsink which may be positioned adjacent to heat generating component(s)) in an effective/efficient manner possibly without compromising effectiveness of shielding (e.g., in view of EMC related concern(s)/issue(s)) as the heatsink may also be configured to form a part/portion of an EMC type enclosure.

It should be appreciated that the embodiments described above may be combined in any manner as appropriate (e.g., one or more embodiments as discussed in the “Detailed Description” section may be combined with one or more embodiments as described in the “Brief Summary” section).

It should be further appreciated by the person skilled in the art that variations and combinations of embodiments described above, not being alternatives or substitutes, may be combined to form yet further embodiments.

In one example, the contact point(s) may include one or both of at least one set of discrete contact points (e.g., a plurality of spring contacts which may be defined along the periphery of the face 102c) and at least one contact point which may correspond to a continuous perimeter (e.g., which may be defined around the opening(s) 102b), in accordance with an embodiment of the disclosure.

In another example, the contact point(s) may include one or both of at least one set of discrete contact points (e.g., a plurality of spring contacts which may be defined around the opening(s) 102b) and at least one contact point which may correspond to a continuous perimeter (e.g., which may be defined along the periphery of the face 102c), in accordance with an embodiment of the disclosure.

In yet another example, an assembly method (not shown) in association with the assembly 100 may be provided, in accordance with an embodiment of the disclosure. The assembly method may, in one embodiment, include providing any one of the apparatus(es) 102, the heat dissipation element(s) 104, and the contact element(s) 106, or any combination thereof. The assembly method may, in one example, further include assembling any one of the apparatus(es) 102, the heat dissipation element(s) 104, and the contact element(s) 106, or any combination thereof, in a manner so as to form the assembly 100, in accordance with an embodiment of the disclosure. The assembly method may, in another example, further include assembling any one of the apparatus(es) 102 and/or the heat dissipation element(s) 104, and/or defining the contact element(s) 106 (e.g., in association with the apparatus(es) 102, or any combination thereof), in a manner so as to form the assembly 100, in accordance with an embodiment of the disclosure. The assembly method may, in yet another example, further include assembling any one of the apparatus(es) 102, the heat dissipation element(s) 104, the contact element(s) 106, and defining the contact element(s) 106 (e.g., in association with the apparatus(es) 102, or any combination thereof), in a manner so as to form the assembly 100, in accordance with an embodiment of the disclosure.

The foregoing description shall be interpreted as illustrative and not be limited thereto. One of ordinary skill in the art would understand that certain modifications may come within the scope of this disclosure. Although the different non-limiting embodiments are illustrated as having specific components or steps, the embodiments of this disclosure are not limited to those combinations. Some of the components or features from any of the non-limiting embodiments may be used in combination with features or components from any of the other non-limiting embodiments. For these reasons, the appended claims should be studied to determine the true scope and content of this disclosure.

1. An apparatus usable with at least one heat dissipation element including at least one protrusion, the apparatus comprising:
a body shaped and dimensioned in a manner so as to be capable of at least one of:
covering at least one component,
including at least one opening defined, and
mating with the heat dissipation element in a manner such that the protrusion is at least positionally aligned with the opening so as to be capable of being thermally coupled to the component to facilitate heat dissipation of heat generated by the component,
wherein, when mated, contact being established between the body and the heat dissipation element such that an electromagnetic compatibility (EMC) type enclosure is formed.

2. The apparatus according to claim 1,
wherein contact established between the body and the heat dissipation element is based on at least one of direct contact and indirect contact, and
wherein the heat dissipation element has been grounded.

3. The apparatus according to claim 1,
wherein contact between the body and the heat dissipation element is based on direct contact such that at least one portion of the body directly contacts the heat dissipation element which has been grounded.

4. The apparatus according to claim 3,
wherein the body is further shaped and dimensioned so as to define at least one contact point capable of establishing contact between the body and the heat dissipation element.

5. The apparatus according to claim 4,
wherein the body is further shaped and dimensioned so as to define a plurality of contact points capable of establishing contact between the body and the heat dissipation element.

6. The apparatus according to claim 5,
wherein the body is further shaped and dimensioned in a manner such that a face is defined, and
wherein, when mated, the face faces the heat dissipation element, and
wherein the plurality of contact points are defined on the face.

7. The apparatus according to claim 6,
wherein the plurality of contact points correspond to a plurality of spring contacts comprising at least a first spring contact and a second spring contact, wherein the first spring contact and second spring contact are discrete contact points to the heat dissipation element.

8. The apparatus according to claim 7,
wherein the spring contacts are at least one of:
defined along the periphery of the face, and
defined in a manner so as to surround the opening.

9. The apparatus according claim 3,
wherein the body is further shaped and dimensioned so as to define a contact point capable of establishing contact between the body and the heat dissipation element.

10. The apparatus according to claim 9,
wherein the contact point corresponds to a continuous perimeter contacting the heat dissipation element when the body and the heat dissipation element are mated.

11. The apparatus according to claim 10,
wherein the contact point corresponds to a continuous perimeter which is defined at least one of:
along the periphery of the face, and
around the opening.

12. The apparatus according to claim 11,
wherein the contact point corresponds to an Electromagnetic Compatibility (EMC) Radio Frequency (RF) dispensed compound.

13. The apparatus according to claim 1,
wherein indirect contact is established between the body and the heat dissipation element by manner of a contact layer disposed between the body and the heat dissipation element.

14. The apparatus according to claim 13,
wherein the contact layer is discrete with respect to at least one of the body and the heat dissipation element.

15. The apparatus according to claim 14,
wherein the contact layer corresponds to an Electromagnetic Compatibility (EMC) pad.

16. The apparatus according to claim 1,
wherein, when mated, contact being established such that the opening is at least one of:
surrounded, and
completely surrounded.

17. The apparatus according to claim 1,
wherein the apparatus corresponds to an Electromagnetic Compatibility (EMC) protected shield covering.

18. The apparatus according to claim 1,
wherein the protrusion is shaped and dimensioned so as to be capable of extending through the opening so as to be at least positionally adjacent to the component such that thermal coupling between the protrusion and the component is capable of being facilitated.

19. The apparatus according to claim 1,
wherein the protrusion is positionally aligned with the opening so as to be positionally aligned with the component such that thermal coupling between the protrusion and the component is capable of being facilitated.

20. An assembly comprising:
a heat dissipation element comprising at least one protrusion; and
an apparatus coupled to the heat dissipation element, the apparatus comprising:
a body shaped and dimensioned in a manner so as to be capable of at least one of:
housing at least one component,
comprising at least one opening defined, and
wherein the heat dissipation element and the apparatus are capable of being coupled in a manner such that the protrusion is at least positionally aligned with the opening,
wherein the protrusion is capable of being thermally coupled to the component to facilitate heat dissipation of heat generated by the component,
wherein, when the heat dissipation element and the apparatus are coupled, contact is established between the body and the heat dissipation element such that an electromagnetic compatibility (EMC) type enclosure is formed.
